(19) United States
(12) Patent Application Publication
(10) Pub. No.: US 2025/0364727 A1
(43) Pub. Date: Nov. 27, 2025

(54) ELECTROMAGNETIC WAVE ABSORBER

(71) Applicant: Mitsubishi Electric Corporation, Tokyo (JP)

(72) Inventor: Satoshi YONEDA, Tokyo (JP)

(73) Assignee: Mitsubishi Electric Corporation, Tokyo (JP)

(21) Appl. No.: 19/293,707

(22) Filed: Aug. 7, 2025

Related U.S. Application Data
(63) Continuation of application No. PCT/JP2023/015273, filed on Apr. 17, 2023.

(51) Int. Cl. H01Q 17/00

(52) U.S. Cl. CPC H01Q 17/008

(57) ABSTRACT

An electromagnetic wave absorber includes multiple resonator units, each of which has SIW resonators, each of which has: a front surface conductor layer formed with a coupling slot into which an electromagnetic wave is introduced; a rear surface conductor layer which is placed opposite to the front surface conductor layer; and a penetration conductor to electrically connect the front surface conductor layer and the rear surface conductor layer, the SIW resonators being different in resonance frequency from each other, and disposed in a multistage form in a lateral direction of the coupling slot, and the multiple resonator units are disposed in a planar form in such a way that the longitudinal direction of the coupling slots belonging to each of the multiple resonator units is oriented in two or more directions.

### CROSS REFERENCE TO RELATED APPLICATION

This application is a Continuation of PCT International Application No. PCT/JP2023/015273, filed on Apr. 17, 2023, which is hereby expressly incorporated by reference into the present application.

### TECHNICAL FIELD

The present disclosure relates to an electromagnetic wave absorber.

### BACKGROUND ART

In relation to electromagnetic wave absorber according to the present disclosure, the invention which relates to a method of disposing an electromagnetic wave absorber (also referred to as the “conventional invention” hereinafter) is disclosed in Patent Literature 1, for example. This conventional invention is made to address a problem of, in consideration of the fact that, in the case of forming a wave absorption layer by arranging electromagnetic wave absorbers, each of which is configured by laminating high permeability amorphous alloy thin strips in a direction in which the surface of a panel extends, in such a way that all of their laminated lines are oriented in the same direction, the wave absorption characteristics degrade when the polarization of electric waves is not limited to horizontal or vertical one, providing a method of disposing the electromagnetic wave absorbers, thereby providing good wave absorption characteristics also when the polarization of electric waves is not limited to horizontal or vertical one. Then, in order to solve this problem, according to the conventional invention, the panel-shaped electromagnetic wave absorbers having the above-mentioned configuration are closely attached on the external wall surface of a building, or the like by arranging the electromagnetic wave absorbers in such a way that electromagnetic wave absorbers in which the directions of the laminated lines of their alloy thin strips are perpendicular to each other have a checkered pattern.

### CITATION LIST

### Patent Literature

Patent Literature 1: JP-A-Hei 5-335778

### SUMMARY OF INVENTION

### Technical Problem

The conventional invention achieves electromagnetic wave absorption characteristics that are independent of the direction of polarization of an electromagnetic wave incident thereon by incorporating the above-mentioned configuration. Further, the above-mentioned conventional invention achieves electromagnetic wave absorption characteristics in a frequency band of 100 MHz to 1 GHz by using the above-mentioned amorphous thin strips made of metallic magnetic substance. However, in the above-mentioned conventional invention, the above-mentioned frequency band depends on the property of the metallic magnetic substance, and it is difficult to set up the frequency band of an electric wave which is an object to be absorbed with flexibility in some cases like the case where it is desired to absorb electromagnetic waves in a specific frequency band within the above-mentioned frequency band or in a specific frequency band outside the above-mentioned frequency band.

The present disclosure is made in order to solve the above-mentioned problem, and it is therefore an object of the present disclosure to provide an electromagnetic wave absorber which makes it possible to set the frequency band of an electromagnetic wave incident thereon which is an object to be absorbed with more flexibility than the conventional electromagnetic wave absorber, irrespective of the direction of polarization of the electromagnetic wave.

### Solution to Problem

An electromagnetic wave absorber according to the present disclosure includes: multiple resonators, each of which has SIW resonators, each of which has: a front surface conductor layer formed with a coupling slot into which an electromagnetic wave is introduced; a rear surface conductor layer which is placed opposite to the front surface conductor layer; and a penetration conductor to electrically connect the front surface conductor layer and the rear surface conductor layer, the SIW resonators being different in resonance frequency from each other, and disposed in a multistage form in a lateral direction of the coupling slot, wherein the multiple resonators are disposed in a planar form in such a way that the longitudinal direction of the coupling slots belonging to each of the multiple resonators is oriented in two or more directions, a length in longitudinal direction of the coupling slots is longer than a half wavelength at a resonance frequency of the SIW resonator having said coupling slots.

### Advantageous Effects of Invention

According to the present disclosure, the electromagnetic wave absorber makes it possible to set the frequency band of an electromagnetic wave incident thereon which is an object to be absorbed with more flexibility than the conventional electromagnetic wave absorber, irrespective of the direction of polarization of the electromagnetic wave.

### BRIEF DESCRIPTION OF DRAWINGS

FIG. 1 is a plan view showing an example of the configuration of an electromagnetic wave absorber according to Embodiment 1;

FIG. 2 is a view showing an example of the configuration of a resonator unit according to Embodiment 1;

FIG. 3A is a plan view of an SIW resonator in Embodiment 1, and FIG. 3B is a cross-sectional view taken along the line A-A in FIG. 3A;

FIG. 4 is a view showing an example in the case of limiting the orientation in the longitudinal directions of open coupling slots in Embodiment 1;

FIGS. 5A and 5B are views showing results of experiments to measure the characteristics of absorption of electromagnetic waves by the electromagnetic wave absorber according to Embodiment 1;

FIGS. 6A to 6C are views showing results of experiments to measure the characteristics of absorption of electromagnetic waves by the electromagnetic wave absorber according to Embodiment 1;

FIG. 7 is a view showing results of experiments to measure the characteristics of absorption of electromagnetic waves by the electromagnetic wave absorber according to Embodiment 1;

FIG. 8 is a plan view showing an example of the configuration of an electromagnetic wave absorber according to Embodiment 2;

FIG. 9 is a plan view showing an example of the configuration of an electromagnetic wave absorber according to Embodiment 3; and

FIG. 10A is a plan view of an SIW resonator in Embodiment 3, and FIG. 10B is a cross-sectional view of the SIW resonator in Embodiment 3.

### DESCRIPTION OF EMBODIMENTS

Hereinafter, the embodiments of the present disclosure will be explained in detail with reference to the drawings.

### Embodiment 1

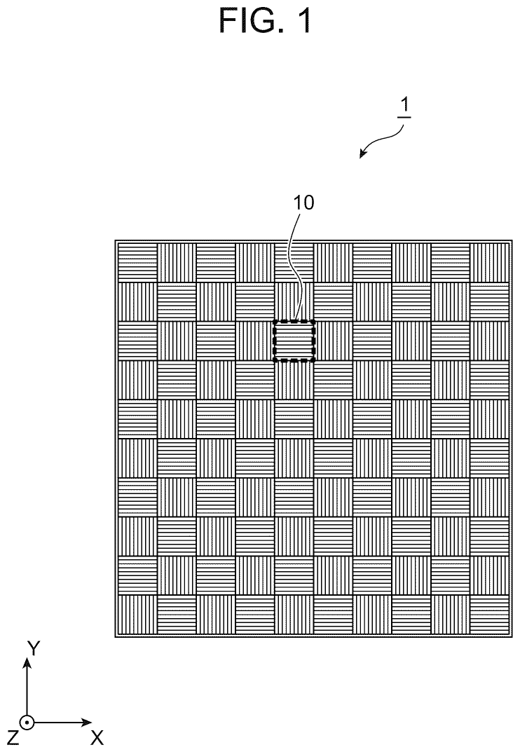

FIG. 1 is a plan view showing an example of the configuration of an electromagnetic wave absorber 1 according to Embodiment 1. The electromagnetic wave absorber 1 is configured in a flat-plate shape, for example, as shown in FIG. 1. In that electromagnetic wave absorber 1, an electromagnetic wave propagates in a direction from the front side of the page of FIG. 1 to the rear side of the page.

Concretely, the electromagnetic wave absorber 1 includes multiple SIW resonator sets (also referred to as “resonator units”) 10 (in the example of FIG. 1, 100 SIW resonator sets) in each of which SIW resonators having mutually different resonance frequencies are disposed in a multistage form. The electromagnetic wave absorber 1 is configured in such a way that those multiple resonator units 10 are closely disposed in a planar form on a substrate which serves as a base. Hereinafter, a resonator unit 10 and SIW resonators which make up the resonator unit 10 will be explained first.

### Resonator Unit 10

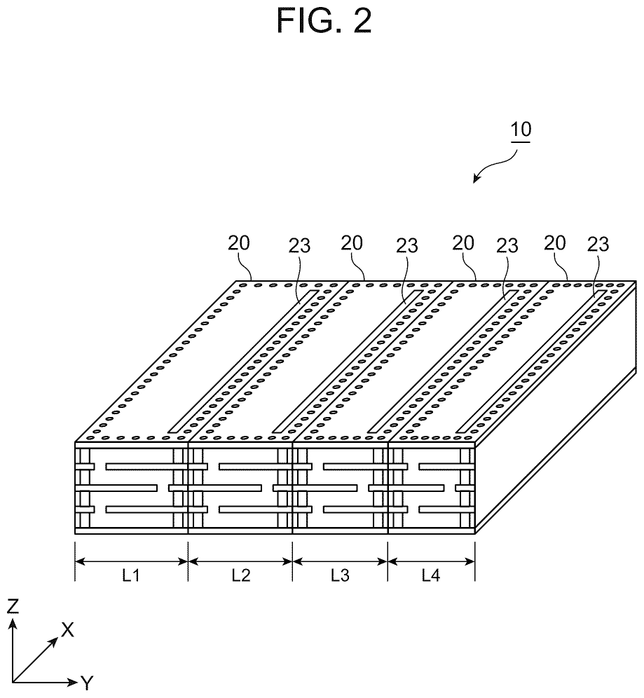

An example of the configuration of a resonator unit 10 is shown in FIG. 2. The resonator unit 10 is configured by disposing SIW resonators having mutually different resonance frequencies in a multistage form. In FIG. 2, an example of the configuration of a resonator unit 10 in which, as an example, SIW resonators having mutually different resonance frequencies are disposed in a four-stage form is shown.

As shown in FIG. 2, the resonator unit 10 is configured in such a way that four SIW resonators having mutually different resonance frequencies are disposed in the multistage form in the lateral directions of coupling slots 23 which will be mentioned later (in the Y direction shown in FIG. 2). At this time, all the longitudinal directions (the X direction shown in FIG. 2) of the four coupling slots 23 belonging to the resonator unit 10 are oriented in the same direction. As a result, the resonator unit 10 has a predetermined resonance frequency band, and can implement a wide band absorption effect which is a result of combining the electromagnetic wave absorption characteristics of the four SIW resonators 20.

### SIW Resonator 20

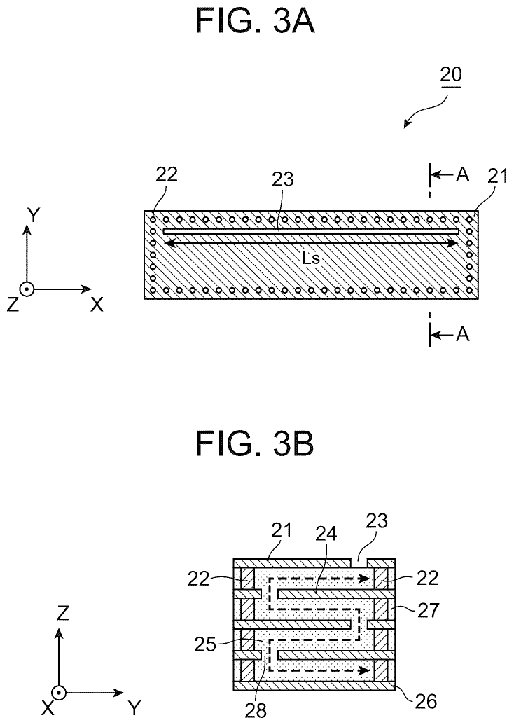

Next, an example of the configuration of an SIW resonator 20 will be explained with reference to FIG. 3. FIG. 3A is a plan view of the SIW resonator 20, and FIG. 3B is a cross-sectional view taken along the A-A line in FIG. 3A. The SIW resonator 20 has a rectangular planar shape (non-square rectangular shape), as shown in FIG. 3A.

The SIW resonator 20 includes a multilayered dielectric substrate 27 and an array of penetration through holes (penetration conductors) 22.

The multilayered dielectric substrate 27 has a configuration in which the multilayered dielectric substrate has four dielectric layers each sandwiched between two different ones of five conductor layers, and two adjacent ones included in those four dielectric layers are partially joined, for example. Here, a front surface conductor layer, out of the five conductor layers, is disposed in a main surface of the multilayered dielectric substrate 27, and a solid conductor pattern 26 which is a rear surface conductor layer, out of the five conductor layers, is disposed in a rear surface of the multilayered dielectric substrate. FIG. 3A shows a plan view including a front surface conductor pattern 21 which is the front surface conductor layer.

As shown in FIG. 3A, the front surface conductor pattern 21 having the penetration through hole array 22 and a coupling slot (coupling hole) 23 is disposed in the main surface of the multilayered dielectric substrate 27. The penetration through hole array 22 is disposed in a rectangular shape along an outer edge of the front surface conductor layer disposed in the main surface of the multilayered dielectric substrate 27. Further, the coupling slot 23 is disposed close to one of the sides in the longitudinal direction of the penetration through hole array 22 disposed in a rectangular shape. At this time, the longitudinal direction of the coupling slot 23 and the longitudinal direction of the penetration through hole array 22 are parallel to each other, and the longitudinal direction of the coupling slot 23 and the lateral direction of the penetration through hole array 22 are perpendicular to each other.

The single coupling slot 23 is disposed in the front surface conductor pattern 21 surrounded by the penetration through hole array 22. As a result, the main surface of the multilayered dielectric substrate 27 surrounded by the penetration through hole array 22 has a region in which the front surface conductor pattern 21 which is the front surface conductor layer is formed, and a dielectric exposed region in which a dielectric layer is exposed through the coupling slot 23.

The penetration through hole array 22 is a penetration conductor layer which electrically connects the front surface conductor layer located in the main surface of the multilayered dielectric substrate 27, and the solid conductor pattern 26 which is the rear surface conductor layer located in the surface opposite to the main surface of the multilayered dielectric substrate 27.

The SIW resonator 20 has a region inside the multilayered dielectric substrate 27, the region being electrically enclosed by the penetration through hole array 22, the front surface conductor pattern 21, second through fourth internal layer conductor patterns 24, and the solid conductor pattern 26 in the rear surface, as shown in FIG. 3B. Here, the penetration through hole array 22 electrically connects the front surface conductor layer and the rear surface conductor layer, thereby forming the electrically enclosed region together with the front surface conductor layer and the rear surface conductor layer.

Further, two adjacent ones of the four dielectric layers 25 are joined at an inner layer coupling hole 28 inside the electrically enclosed region. As a result, in the SIW resonator 20, an electromagnetic wave propagation path (shown by a dotted line arrow in FIG. 3B) which extends from the coupling slot 23 to the rear surface conductor layer and which is inside the multilayered dielectric substrate 27 is formed in such a way as to be folded back three times, as shown in FIG. 3B. In this case, the SIW resonator 20 has a thickness (the length in the Z direction shown in FIG. 3B) of approximately 2.0 mm to 3.0 mm.

Further, a certain SIW resonator 20 is designed in such a way that the spacing L1 between both sides in the lateral direction is approximately 1/16 wavelength at frequency f1. Further, that SIW resonator 20 is formed in such a way that the length (shown by a reference sign Ls in FIG. 3A) in the longitudinal direction of the coupling slot 23 is longer than half wavelength at frequency f1. In addition, in the SIW resonator 20, the length (shown by the dotted line arrow in FIG. 3B) of the propagation path inside the multilayered dielectric substrate 27 corresponds to one-quarter wavelength at frequency f1.

As a result, in the SIW resonator 20, cavity resonance occurs at frequency f1 and an electromagnetic wave of the frequency f1 incident on the SIW resonator 20 is absorbed. More specifically, the SIW resonator 20 can achieve electromagnetic shielding characteristics with an extremum at frequency f1 by itself. Especially, in the SIW resonator 20, because the coupling slot 23 is formed in such a way as to have a length in the longitudinal direction which is longer than half wavelength at frequency f1, an electromagnetic wave of frequency f1 can be efficiently absorbed.

By then making the resonance frequencies in the four SIW resonators 20 different from one another in the resonator unit 10, for example, setting them to frequencies f1 to f4, the resonator unit 10 in which the four SIW resonators are disposed in a multistage form can implement wide band electromagnetic shielding characteristics having extrema at frequencies f1 to f4. In this case, in the resonator unit 10, the spacings L1 to L4 between both sides in the lateral directions of the SIW resonators 20 are designed in such a way as to be approximately 1/16 wavelengths at resonance frequencies f1 to f4, respectively. Further, in the resonator unit 10, it also becomes possible to adjust the acquired electromagnetic shielding characteristics using a method of selecting the resonance frequency of each of the SIW resonators 20.

Although the example of the configuration of the resonator unit 10 in which the SIW resonators 20 are disposed in the four-stage form is explained above, the number of stages of SIW resonators 20 in the resonator unit 10 is not limited to four, and should just be two or more. Further, although the configuration in which the propagation path which extends from the coupling slot 23 to the rear surface conductor layer and which is inside the multilayered dielectric substrate 27 is folded back three times is explained above, the number of times that the propagation path is folded back is not limited to three, and should just be two or more.

Because the length in the lateral direction (in the Y direction shown in FIG. 3A) of one SIW resonator 20 becomes shorter with an increase in the number of times that the propagation path is folded back in the SIW resonator 20, the number of SIW resonators 20 which can be incorporated into one resonator unit 10 can be increased with the increase in the number of times. On the other hand, the thickness (the length in the Z-direction shown in FIG. 3B) of one SIW resonator 20 becomes larger with the increase in the number of times that the propagation path is folded back in the SIW resonator 20. As mentioned above, in the resonator unit 10, the number of incorporable SIW resonators 20 and the thickness of each SIW resonator 20 (resonator unit 10) which vary with the number of times that the propagation path is folded back in the SIW resonator 20 have a trade-off relation. Therefore, it is desirable that the number of times that the propagation path is folded back in one SIW resonator 20 is set to a proper number according to the number of SIW resonators 20 incorporated into one resonator unit 10 and the thickness of the SIW resonator 20.

### Example of the Arrangement of Resonator Units 10

The electromagnetic wave absorber 1 is configured in such a way that multiple resonator units 10 (100 resonator units in the example shown in FIG. 1) each of which is configured as above are closely disposed in a planar form on a substrate which serves as a base.

At this time, each of the resonator units 10 can be configured in such a way that all the resonator units 10 have the same resonance frequency band (e.g., the frequencies f1 to f4) or in such a way that the resonance frequency band (e.g., the frequencies f1 to f4) which a resonator unit 10 has overlaps, at least partially, with the resonance frequency band (e.g., frequencies f2 to f5) which another resonator unit 10 has. In the former case, the electromagnetic wave absorber 1 can implement excellent absorption characteristics, especially in the specific frequency band (e.g., the frequencies f1 to f4). Further, in the latter case, the electromagnetic wave absorber 1 can implement excellent absorption characteristics in a frequency band wider than that in the former case. The determination of the resonance frequency band of each of the resonator units 10 should just be performed as appropriate in accordance with the frequency band of an electromagnetic wave which is desired to be actually absorbed.

Further, in the electromagnetic wave absorber 1, the planar shape of one resonator unit 10 is a square, as shown in FIG. 1. Further, in the electromagnetic wave absorber 1, the longitudinal directions of the coupling slots 23 belonging to one resonator unit 10 are the same in orientation as each other, as mentioned above. In FIG. 1, for the sake of simplicity of illustration, the longitudinal directions of the coupling slots 23 belonging to one resonator unit 10 are shown by vertical or horizontal straight lines.

Further, in the electromagnetic wave absorber 1, the resonator units 10 are arranged in such a way that the longitudinal directions of the coupling slots 23 belonging to a resonator unit 10 are oriented in alternate direction with respect to the longitudinal directions of the coupling slots 23 belonging to the four resonator units 10 adjacent to that resonator unit 10 (that is, so as to be perpendicular to them), as shown in FIG. 1.

In this case, in the electromagnetic wave absorber 1, the longitudinal directions of the coupling slots 23 belonging to 50 resonator units 10, out of the 100 resonator units 10, are oriented in the X direction shown in FIG. 1, while the longitudinal directions of the coupling slots 23 belonging to 50 resonator units 10, out of the 100 resonator units 10, are oriented in the Y direction shown in FIG. 1. More specifically, in the electromagnetic wave absorber 1, the longitudinal directions of the coupling slots 23 belonging to the 100 resonator units 10 are oriented in the two directions (two types). Further, in the electromagnetic wave absorber 1, the 100 resonator units 10 which are classified into the two types in accordance with the longitudinal directions of the coupling slots 23 are disposed in a mosaic periodic pattern as shown in FIG. 1 (the two types of resonator units are disposed alternately).

The example in which the resonator units 10 are arranged in such a way that the longitudinal directions of the coupling slots 23 belonging to a resonator unit 10 are oriented in alternate directions with respect to the longitudinal directions of the coupling slots 23 belonging to all the resonator units 10 (four resonator units) adjacent to that resonator unit 10 (that is, so as to be perpendicular to them) is explained above. However, the electromagnetic wave absorber 1 is not limited to this example, and the resonator units 10 may be disposed in such a way that the longitudinal directions of the coupling slots 23 belonging to a resonator unit 10 are different from the longitudinal directions of the coupling slots 23 belonging to at least one of the resonator units 10 adjacent to that resonator unit 10. An example of that will be explained in Embodiment 2.

### Advantageous Effect of the Electromagnetic Wave Absorber 1

Next, an advantageous effect of the electromagnetic wave absorber 1 will be explained. Hereinafter, the advantageous effect of the electromagnetic wave absorber 1 will be explained on the basis of results of experiments to measure the characteristics of absorption of electromagnetic waves by the electromagnetic wave absorber 1, the experiments being conducted by the inventors et al. of the electromagnetic wave absorber 1 (also simply referred to as the “inventors et al.” hereinafter).

First, using the above-mentioned method, the inventor et al. configured multiple resonator units 10 (100 resonator units in this example) in such a way that the resonator units have predetermined electromagnetic wave absorption characteristics in a specific frequency band centered at, for example, 2.52 GHz. The inventers et al. then configured the electromagnetic wave absorber 1 by closely arranging those 100 resonator units 10 in a planar form, as shown in FIG. 1.

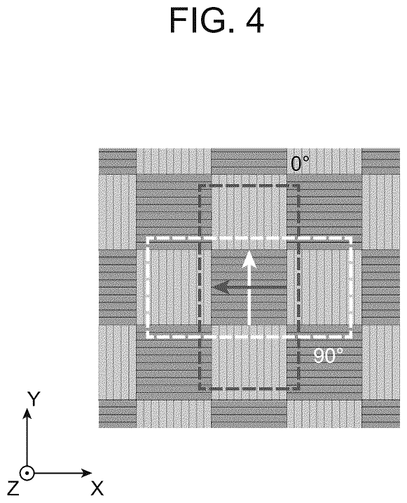

As shown in FIG. 4, the inventers et al. then attach copper foil tapes to the coupling slots 23 belonging to the 50 resonator units 10 in which the longitudinal directions of their coupling slots 23 are oriented in the Y direction shown in FIG. 4, out of the 100 resonator units 10, to close the slots, thereby limiting the longitudinal directions of the open coupling slots 23 to the X direction shown in FIG. 4. The inventers et al. then measured the electromagnetic wave absorptivity of the electromagnetic wave absorber 1 while varying the direction of polarization of an electromagnetic wave to be incident on the electromagnetic wave absorber 1 from 0 degrees to 90 degrees. Here, it is assumed that the X direction shown in FIG. 4 is at 0 degrees, and the Y direction shown in FIG. 4 is at 90 degrees.

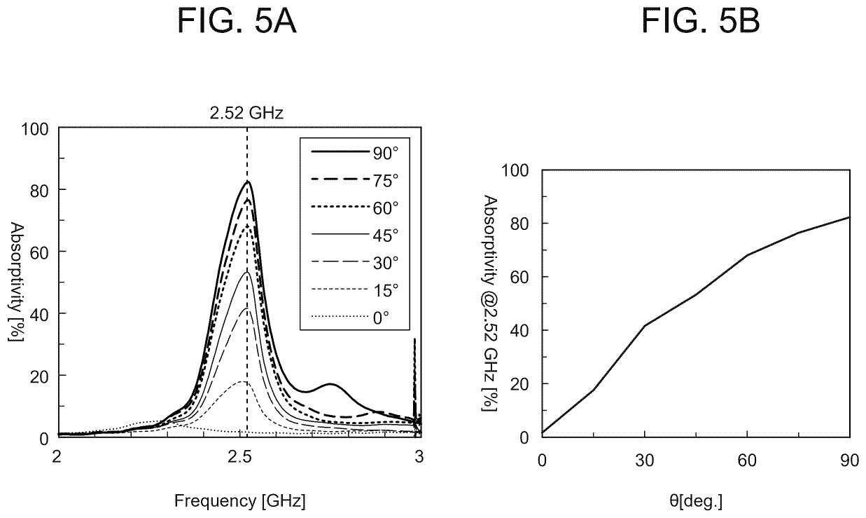

Results of the measurement are shown in FIGS. 5A and 5B. In FIG. 5A, the horizontal axis shows the frequency (GHz) of the electromagnetic wave, and the vertical axis shows the electromagnetic wave absorptivity (%). Further, in FIG. 5B, the horizontal axis shows the direction (deg) of polarization of the electromagnetic wave, and the vertical axis shows the electromagnetic wave absorptivity (%) when the frequency of the electromagnetic wave is 2.52 GHz.

As shown in FIGS. 5A and 5B, the electromagnetic wave absorption characteristics vary nearly linearly with the direction of polarization of the incident electromagnetic wave. In this example, the electromagnetic wave absorptivity has a minimum (approximately 0) when the direction of polarization of the electromagnetic wave is 0 degrees, while the electromagnetic wave absorptivity has a maximum (approximately 80%) when the direction of polarization of the electromagnetic wave is 90 degrees. More specifically, in this example, the closer the angles between the direction of polarization of the electromagnetic wave and the longitudinal direction of the coupling slots 23 which are open in the electromagnetic wave absorber 1 are to 90 degrees, the higher the electromagnetic wave absorptivity becomes. On the other hand, in this example, although a predetermined absorptivity is obtained in the specific frequency band centered at 2.52 GHz, the absorptivity is maintained at a low value in other frequency bands, as shown in FIG. 5A. This shows that the electromagnetic wave absorber 1 allows electromagnetic waves in bands other than the specific frequency band to pass therethrough without absorbing them.

Next, the inventers et al. removed the above-mentioned copper foil tapes and removed the limit on the longitudinal directions of the coupling slots 23 which are open in the electromagnetic wave absorber 1. The inventers et al. measured the electromagnetic wave absorptivity of the electromagnetic wave absorber 1 while varying the direction of polarization of the electromagnetic wave to be incident on the electromagnetic wave absorber 1 from 90 degrees to 0 degrees.

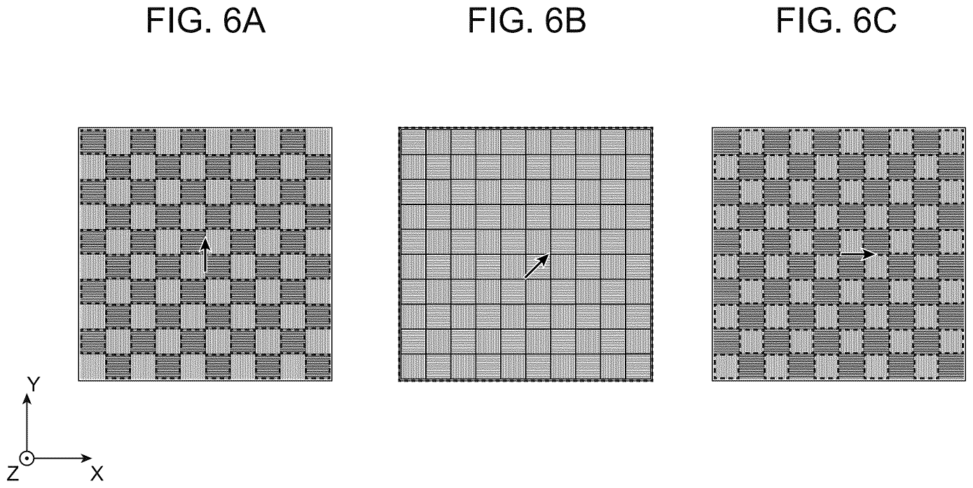

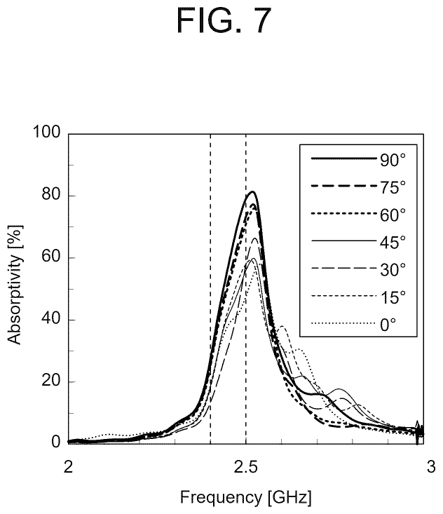

Results of the measurement are shown in FIGS. 6 and 7. FIG. 6A is a view showing the state of coupling between the electromagnetic wave and a resonator unit 10 in the case where the direction of polarization of the electromagnetic wave to be incident on the electromagnetic wave absorber 1 is set to 90 degrees (also referred to as “Condition 1” hereinafter). Similarly, FIG. 6B is a view showing the state of coupling between the electromagnetic wave and the resonator unit 10 in the case where the direction of polarization of the electromagnetic wave to be incident on the electromagnetic wave absorber 1 is set to 45 degrees (also referred to as “Condition 2” hereinafter), and FIG. 6C is a view showing the state of coupling between the electromagnetic wave and the resonator unit 10 in the case where the direction of polarization of the electromagnetic wave to be incident on the electromagnetic wave absorber 1 is set to 0 degrees (also referred to as “Condition 3” hereinafter). In FIGS. 6A to 6C, the direction of polarization of the electromagnetic wave is shown by a solid arrow. Further, in FIG. 7, the horizontal axis shows the frequency (GHz) of the electromagnetic wave, and the vertical axis shows the electromagnetic wave absorptivity (%).

As shown in FIG. 6A, in Condition 1, the 50 resonator units 10 which are included in the 100 resonator units 10 and in which the directions of the widths of the coupling slots 23 are at 0 degrees are strongly coupled with the electromagnetic wave. In other words, in Condition 1, the resonator units 10 included in the 100 resonator units 10 and having coupling slots 23 whose longitudinal directions form an angle of 90 degrees with the direction of polarization (90 degrees) of the electromagnetic wave are strongly coupled with the electromagnetic wave.

Further, as shown in FIG. 6B, in Condition 2, all the 100 resonator units 10 are moderately coupled with the electromagnetic wave. In other words, in Condition 2, all the angles which the longitudinal directions of the coupling slots 23 included in the 100 resonator units 10 form with the direction of polarization (45 degrees) of the electromagnetic wave are 45 degrees, and, as a result, all the 100 resonator units 10 are moderately coupled with the electromagnetic wave.

Further, as shown in FIG. 6C, in Condition 3, the 50 resonator units 10 which are included in the 100 resonator units 10 and in which the longitudinal directions of the coupling slots 23 are at 90 degrees are strongly coupled with the electromagnetic wave. In other words, in Condition 3, the resonator units 10 included in the 100 resonator units 10 and having the coupling slots 23 whose longitudinal directions form an angle of 90 degrees with the direction of polarization (0 degrees) of the electromagnetic wave are strongly coupled with the electromagnetic wave.

As mentioned above, in the electromagnetic wave absorber 1, even though the direction of polarization of the electromagnetic wave incident thereon varies from 90 degrees to 0 degrees, at least 50 resonator units 10 have angles of 45 degrees or more between the longitudinal directions of their coupling slots 23 and the direction of polarization of the electromagnetic wave. In other words, in the electromagnetic wave absorber 1, even though the direction of polarization of the electromagnetic wave incident thereon varies from 90 degrees to 0 degrees, all the angles between the longitudinal directions of the coupling slots 23 and the direction of polarization of the electromagnetic wave does not become less than 45 degrees simultaneously. Therefore, the electromagnetic wave absorber 1 can implement predetermined electromagnetic wave absorption characteristics in the specific frequency band centered at 2.52 GHz, irrespective of the direction of polarization of the electromagnetic wave incident thereon, as shown in FIG. 7.

Further, in the electromagnetic wave absorber 1, the SIW resonators 20 that make up a resonator unit 10 are very thin, with a thickness of approximately 2.0 mm to 3.0 mm. As a result, the entire electromagnetic wave absorber 1 can be made to have a similar thickness, and a thickness reduction can be achieved. For example, in the above-mentioned conventional invention, the thickness of the electromagnetic wave absorber is 10 mm, and, in comparison to this absorber, the electromagnetic wave absorber 1 can be further reduced in thickness.

In the above-mentioned explanation, the example in which the electromagnetic wave absorber 1 implements the predetermined electromagnetic wave absorption characteristics in the specific frequency band centered at 2.52 GHz is explained. However, this is only an example, and the electromagnetic wave absorber 1 may be aimed at a frequency band other than the above-mentioned frequency band.

In the above-mentioned explanation, the example in which a resonator unit 10 is configured in such a way that SIW resonators 20 having mutually different resonance frequencies are disposed in a multistage form is explained. However, a resonator unit 10 may be configured in such a way that SIW resonators 20 having the same resonance frequency are disposed in a multistage form, and, in that case, the multiple resonator units 10 should just have different resonance frequencies. More specifically, in the electromagnetic wave absorber 1, by making the multiple resonator units 10 have different resonance frequencies, instead of making each of the resonator units 10 have a predetermined resonance frequency band, a predetermined resonance frequency band may be provided for the whole of the multiple resonator units 10.

Further, in the above-mentioned explanation, the example in which the 100 resonator units 10 which are classified into the two types in accordance with the longitudinal directions of the coupling slots 23 are disposed in a mosaic periodic pattern as shown in FIG. 1 (the two types of resonator units are disposed alternately) is explained. However, the electromagnetic wave absorber 1 is not limited to this example, and, for example, the region of the electromagnetic wave absorber 1 shown in the plan view of FIG. 1 may be divided into four regions, and one of the types may be disposed in the upper right region and in the lower left region while the other one of the types may be disposed in the upper left region and in the lower right region. More specifically, in the electromagnetic wave absorber 1, the multiple resonator units 10 should just be disposed in a planar form in such a way that the longitudinal directions of the coupling slots belonging to each of the resonator units 10 are oriented in two or more ones (two or more types).

As mentioned above, according to Embodiment 1, the electromagnetic wave absorber 1 includes: the multiple resonator units 10 in each of which the SIW resonators 20 each having the front surface conductor layer 21 in which the coupling slot 23 into which an electromagnetic wave is introduced is formed, the rear surface conductor layer 26 which is placed opposite to the front surface conductor layer 21, and the penetration conductors 22 to electrically connect the front surface conductor layer 21 and the rear surface conductor layer 26, and having mutually different resonance frequencies are disposed in a multistage form in the lateral direction of the coupling slot 23, and the multiple resonator units 10 are arranged in a planar form in such a way that the coupling slots 23 belonging to each of the resonator units 10 have two or more longitudinal directions. As a result, the electromagnetic wave absorber 1 according to Embodiment 1 makes it possible to set the frequency band of an electromagnetic wave incident thereon which is an object to be absorbed with more flexibility than the conventional electromagnetic wave absorber, irrespective of the direction of polarization of the electromagnetic wave.

Especially, because in the electromagnetic wave absorber 1 according to Embodiment 1, its frequency band does not depend on the property of the metallic magnetic substance, unlike in the conventional invention, the electromagnetic wave absorber 1 makes it possible to set the frequency band of an electromagnetic wave which is an object to be absorbed with more flexibility than the conventional invention. Further, because in the electromagnetic wave absorber 1 according to Embodiment 1, the thicknesses of the SIW resonators 20 which make up a resonator unit 10 are very thin, the entire electromagnetic wave absorber 1 can be reduced in thickness.

Further, the longitudinal directions of the coupling slots 23 belonging to one resonator unit 10 are the same, and the multiple resonator units 10 are arranged in such a way that the longitudinal directions of the coupling slots 23 belonging to a resonator unit 10 are different from the longitudinal directions of the coupling slots 23 belonging to the resonator units 10 adjacent to that resonator unit 10. As a result, the electromagnetic wave absorber 1 according to Embodiment 1 can implement predetermined electromagnetic wave absorption characteristics, irrespective of the direction of polarization of an electromagnetic wave incident thereon.

Further, the coupling slot 23 has a length in the longitudinal direction which is longer than half wavelength at the resonance frequency of the SIW resonator 20 which has the coupling slot 23. As a result, the electromagnetic wave absorber 1 according to Embodiment 1 can efficiently absorb an electromagnetic wave having the resonance frequency.

Further, each of the multiple resonator units 10 has a square planar shape, and the multiple resonator units 10 are arranged in a planar form in such a way that the longitudinal directions of the coupling slots 23 belonging to each of the resonator units 10 are oriented in two directions. As a result, the electromagnetic wave absorber 1 according to Embodiment 1 can implement predetermined electromagnetic wave absorption characteristics, irrespective of the direction of polarization of an electromagnetic wave incident thereon, and facilitates the arrangement of the multiple resonator units 10.

Further, the multiple resonator units 10 are classified into at least two types according to the longitudinal directions of the coupling slots 23 belonging to each of the resonator units 10, and the classified resonator units 10 of at least the two types are disposed in a mosaic periodic pattern. As a result, the electromagnetic wave absorber 1 according to Embodiment 1 can implement predetermined electromagnetic wave absorption characteristics, irrespective of the direction of polarization of an electromagnetic wave incident thereon.

Further, the front surface conductor layer 21 has N+1 (N>=2) conductor layers and N dielectric layers each of which is sandwiched between two different ones of the N+1 conductor layers, and is located in the main surface of the multilayered dielectric substrate 27 in which two adjacent ones included in the N dielectric layers are partially connected, the rear surface conductor layer 26 is located in the surface opposite to the main surface of the multilayered dielectric substrate 27, the penetration conductors 22 electrically connect the front surface conductor layer 21 and the rear surface conductor layer 26, to form an electrically closed region together with the front surface conductor layer 21 and the rear surface conductor layer 26, the main surface of the multilayered dielectric substrate 27, which is surrounded by the penetration conductors 22, has a region in which the front surface conductor layer 21 is formed, and a dielectric exposed region in which a dielectric layer is exposed through the coupling slot 23 formed in the front surface conductor layer 21, and a region in which the two adjacent dielectric layers are partially connected is inside the electrically closed region. As a result, the electromagnetic wave absorber 1 according to Embodiment 1 can implement the multilayering of the SIW resonators 20 and a size reduction in the lateral direction, and can increase the number of SIW resonators 20 incorporated into one resonator unit 10.

Further, each of the resonator units 10 has a predetermined resonance frequency band because, in that resonator unit, the SIW resonators 20 having mutually different resonance frequencies are disposed in a multistage form, and the resonance frequency bands of the resonator units 10 are the same. As a result, the electromagnetic wave absorber 1 according to Embodiment 1 can implement excellent absorption characteristics, especially in the specific frequency band.

Further, each of the resonator units 10 has a predetermined resonance frequency band because, in that resonator unit, the SIW resonators 20 having mutually different resonance frequencies are disposed in a multistage form, and the resonance frequency band of one of the resonator units 10 overlaps at least partially with the resonance frequency band of another one of the resonator units 10. As a result, the electromagnetic wave absorber 1 according to Embodiment 1 can implement excellent absorption characteristics in a frequency band wider than that in the case where the resonance frequency bands of the resonator units 10 are the same.

Further, according to Embodiment 1, the electromagnetic wave absorber 1 includes: the multiple resonator units 10 in each of which the SIW resonators 20 each having the front surface conductor layer 21 in which the coupling slot 23 into which an electromagnetic wave is introduced is formed, the rear surface conductor layer 26 which is placed opposite to the front surface conductor layer 21, and the penetration conductors 22 to electrically connect the front surface conductor layer 21 and the rear surface conductor layer 26, and having the same resonance frequency are disposed in a multistage form in the lateral direction of the coupling slot 23, and the multiple resonator units 10 have mutually different resonance frequencies and are arranged in a planar form in such a way that the coupling slots 23 belonging to each of the resonator units 10 have two or more longitudinal directions. As a result, the electromagnetic wave absorber 1 according to Embodiment 1 makes it possible to set the frequency band of an electromagnetic wave incident thereon which is an object to be absorbed with more flexibility than the conventional electromagnetic wave absorber, irrespective of the direction of polarization of the electromagnetic wave.

### Embodiment 2

In Embodiment 1, the example in which the resonator units 10 are arranged in such a way that the longitudinal directions of the coupling slots 23 belonging to a resonator unit 10 are different from the longitudinal directions of the coupling slots 23 belonging to all the resonator units 10 adjacent to that resonator unit 10 is explained. In Embodiment 2, a configuration in which resonator units 10 are arranged in such a way that the longitudinal directions of coupling slots 23 belonging to a resonator unit 10 are different from the longitudinal directions of coupling slots 23 belonging to at least one of resonator units 10 adjacent to that resonator unit 10 will be explained.

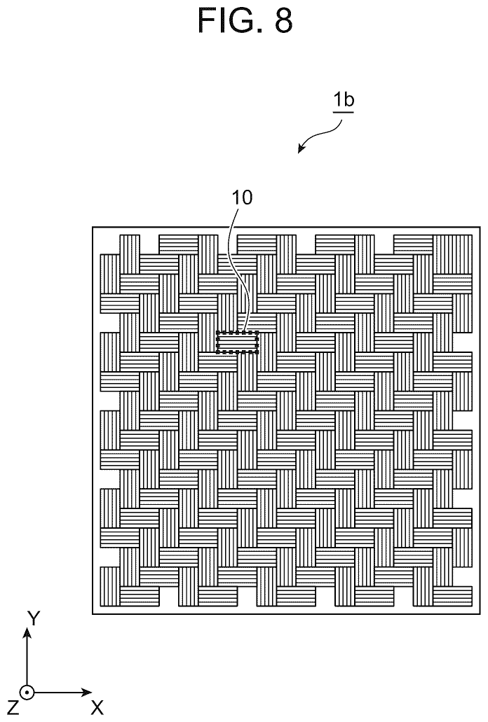

FIG. 8 is a plan view showing an example of the configuration of an electromagnetic wave absorber 1b according to Embodiment 2. The electromagnetic wave absorber 1b according to Embodiment 2 differs from the electromagnetic wave absorber 1 according to Embodiment 1 in that each of the multiple resonator units 10 has a non-square rectangular planar shape. Because the other components of the electromagnetic wave absorber 1b according to Embodiment 2 are the same as those of the electromagnetic wave absorber 1 according to Embodiment 1, the components are denoted by the same reference signs and an explanation of the components will be omitted hereinafter.

In the electromagnetic wave absorber 1b, the planar shape of each of the multiple resonator units 10 is a rectangle in which the length of the long side is twice the length of the short side, as shown in FIG. 8. The configuration of SIW resonators 20 used in the electromagnetic wave absorber 1b is the same as that of the SIW resonators 20 explained in Embodiment 1.

Further, in the electromagnetic wave absorber 1b, the multiple resonator units 10 are arranged in such a way that the longitudinal directions of the coupling slots 23 belonging to a resonator unit 10 are different from the longitudinal directions of the coupling slots 23 belonging to at least one of the resonator units 10 adjacent to that resonator unit 10. For example, in the example shown in FIG. 8, other six resonator units 10 are adjacent to a resonator unit 10, and the longitudinal directions of the coupling slot 23 belonging to four ones of the other resonator units 10 are different from (perpendicular to) the longitudinal directions of the coupling slot 23 belonging to that resonator unit 10.

Further, in the electromagnetic wave absorber 1b, the multiple resonator units 10 are arranged in a planar form in such a way that the longitudinal directions of the coupling slots 23 belonging to each of the resonator units 10 are oriented in two directions (two types), like those of Embodiment 1. Further, in the electromagnetic wave absorber 1b, the resonator units 10 which are classified into the two types in accordance with the longitudinal directions of the coupling slots 23 are disposed in a mosaic periodic pattern as shown in FIG. 8 (the two types of resonator units are disposed at predetermined periods).

### Advantageous Effect of the Electromagnetic Wave Absorber 1b

The electromagnetic wave absorber 1b according to Embodiment 2 also basically provides the same advantageous effect as the electromagnetic wave absorber 1 according to Embodiment 1. More specifically, also in the electromagnetic wave absorber 1b according to Embodiment 2, even though the direction of polarization of an electromagnetic wave incident thereon varies from 90 degrees to 0 degrees, at least one-half of the resonator units 10 have angles of 45 degrees or more between the longitudinal directions of their coupling slots 23 and the direction of polarization of the electromagnetic wave, like in the electromagnetic wave absorber 1 according to Embodiment 1. In other words, in the electromagnetic wave absorber 1b, even though the direction of polarization of the electromagnetic wave incident thereon varies from 90 degrees to 0 degrees, the angles between the longitudinal directions of the coupling slots 23 and the direction of polarization of the electromagnetic wave does not become less than 45 degrees simultaneously. Therefore, the electromagnetic wave absorber 1b can also implement predetermined electromagnetic wave absorption characteristics in a specific frequency band, irrespective of the direction of polarization of the electromagnetic wave incident thereon.

In the above-mentioned explanation, the example in which the planar shape of each of the multiple resonator units 10 is a rectangle in which the length of the long side is twice the length of the short side is explained. However, the electromagnetic wave absorber 1b is not limited to this example, and, for example, the planar shape of each of the multiple resonator units 10 may be a rectangle in which the length of the long side is three times the length of the short side.

However, when the ratio of the length of the long side and the length of the short side is changed, the number of resonator units 10 which can be disposed on a substrate which is a base or the ratio of the resonator units 10 in which the longitudinal directions of the coupling slots 23 are the X direction and the resonator units 10 in which the longitudinal directions of the coupling slots 23 are the Y direction changes with the change in the ratio of the length of the long side and the length of the short side. Therefore, when configuring the electromagnetic wave absorber 1b, it is desirable to determine the ratio of the length of the long side and the length of the short side of each resonator unit 10 in consideration of the desired electromagnetic wave absorption characteristics. Further, in the electromagnetic wave absorber 1b, by determining the ratio of the length of the long side and the length of the short side in this way, the electromagnetic wave absorption characteristics acquired for the direction of polarization of the electromagnetic wave can be customized with flexibility.

As mentioned above, according to Embodiment 2, in the electromagnetic wave absorber 1b, the longitudinal directions of the coupling slots 23 belonging to one resonator unit 10 are the same, and the multiple resonator units 10 are arranged in such a way that the longitudinal directions of the coupling slots 23 belonging to a resonator unit 10 are different from the longitudinal directions of the coupling slots 23 belonging to at least one of the resonator units 10 adjacent to that resonator unit 10. As a result, the electromagnetic wave absorber 1b according to Embodiment 2 makes it possible to set the frequency band of an electromagnetic wave incident thereon which is an object to be absorbed with more flexibility than the conventional electromagnetic wave absorber, irrespective of the direction of polarization of the electromagnetic wave, like that in Embodiment 1.

Further, each of the multiple resonator units 10 has a non-square rectangular planar shape, and the multiple resonator units 10 are arranged in a planar form in such a way that the longitudinal directions of the coupling slots 23 belonging to each of the resonator units 10 are two ones. As a result, the electromagnetic wave absorber 1b according to Embodiment 2 can customize the electromagnetic wave absorption characteristics acquired for the direction of polarization of the electromagnetic wave with flexibility, in addition to the advantageous effect of Embodiment 1.

### Embodiment 3

In Embodiment 3, an example in which a resonator unit 10 has a planar shape which is a rhombus whose one interior angle is 60 degrees will be explained as a variation of the planar shape of the resonator unit 10.

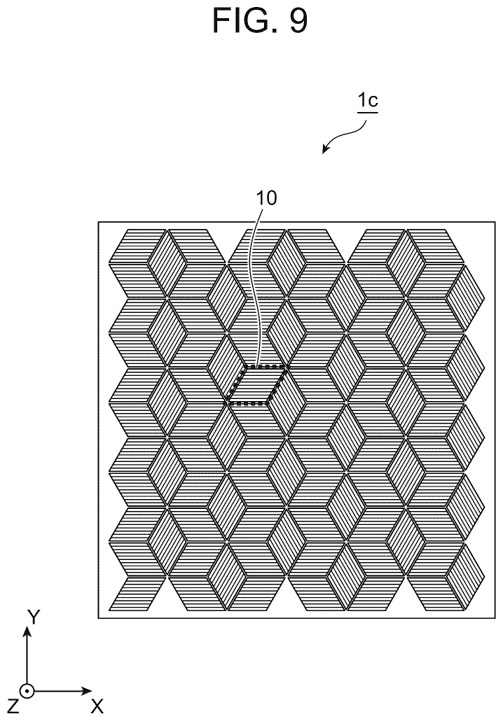

FIG. 9 is a plan view showing an example of the configuration of an electromagnetic wave absorber 1c according to Embodiment 3. The electromagnetic wave absorber 1c according to Embodiment 3 differs from the electromagnetic wave absorber 1 according to Embodiment 1 in that the planar shape of each of multiple resonator units 10 is a rhombus whose one interior angle is 60 degrees, and in that the planar shape of each of SIW resonators 20 is a parallelogram. Because the other components of the electromagnetic wave absorber 1c according to Embodiment 3 are the same as those of the electromagnetic wave absorber 1 according to Embodiment 1, the components are denoted by the same reference signs and an explanation of the components will be omitted hereinafter.

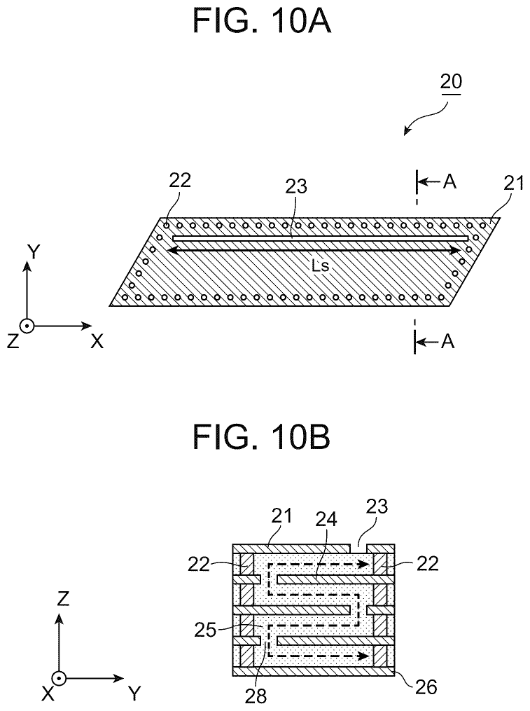

In the electromagnetic wave absorber 1c, the planar shape of each of the multiple resonator units 10 is a rhombus whose one interior angle is 60 degrees, as shown in FIG. 9. Further, the planar shape of each of the SIW resonators 20 used in the electromagnetic wave absorber 1c is a parallelogram, as shown in FIG. 10A. Each component of each of the SIW resonators 20 and a cross-sectional view shown in FIG. 10B are the same as those of each of the SIW resonators 20 explained in Embodiment 1.

Further, in the electromagnetic wave absorber 1c, the multiple resonator units 10 are arranged in such a way that the longitudinal directions of coupling slots 23 belonging to a resonator unit 10 are different from the longitudinal directions of coupling slots 23 belonging to resonator units 10 adjacent to that resonator unit 10. For example, in the example of FIG. 9, four other resonator units 10 are adjacent to a resonator unit 10, and the longitudinal directions of the coupling slots 23 belonging to those four resonator units 10 are different from the longitudinal directions of the coupling slots 23 belonging to that resonator unit 10.

Further, in the electromagnetic wave absorber 1c, the multiple resonator units 10 are arranged in a planar form in such a way that the longitudinal directions of the coupling slot 23 belonging to each of the resonator units 10 are oriented in three directions (three types), unlike those of Embodiment 1. Further, in the electromagnetic wave absorber 1c, the resonator units 10 which are classified into the three types in accordance with the longitudinal directions of the coupling slots 23 are disposed in a mosaic periodic pattern as shown in FIG. 9 (the three types of resonator units are disposed at predetermined periods).

### Advantageous Effect of the Electromagnetic Wave Absorber 1c

Basically, the electromagnetic wave absorber 1c according to Embodiment 3 provides the same advantageous effect as that provided by the electromagnetic wave absorber 1 according to Embodiment 1. More specifically, also in the electromagnetic wave absorber 1c according to Embodiment 3, even though the direction of polarization of an electromagnetic wave incident thereon varies from 90 degrees to 0 degrees, at least one-third of the resonator units 10 have angles of 45 degrees or more between the longitudinal directions of their coupling slots 23 and the direction of polarization of the electromagnetic wave, like in the electromagnetic wave absorber 1 according to Embodiment 1. In other words, in the electromagnetic wave absorber 1c, even though the direction of polarization of the electromagnetic wave incident thereon varies from 90 degrees to 0 degrees, the angles between the longitudinal directions of the coupling slots 23 and the direction of polarization of the electromagnetic wave does not become less than 45 degrees simultaneously. Therefore, the electromagnetic wave absorber 1c can also implement predetermined electromagnetic wave absorption characteristics in a specific frequency band, irrespective of the direction of polarization of the electromagnetic wave incident thereon.

As mentioned above, according to Embodiment 3, each of the multiple resonator unit 10 has a planar shape which is a rhombus whose one interior angle is 60 degrees, and the multiple resonator units 10 are arranged in a planar form in such a way that the longitudinal directions of the coupling slot 23 belonging to each of the resonator units 10 are three ones. As a result, the electromagnetic wave absorber 1c according to Embodiment 3 makes it possible to set the frequency band of an electromagnetic wave incident thereon which is an object to be absorbed with more flexibility than the conventional electromagnetic wave absorber, irrespective of the direction of polarization of the electromagnetic wave, like that in Embodiment 1.

It is to be understood that an arbitrary combination of two or more of the above-mentioned embodiments can be made, various changes can be made in an arbitrary component according to any one of the above-mentioned embodiments, or an arbitrary component according to any one of the above-mentioned embodiments can be omitted within the scope of the present disclosure.

### INDUSTRIAL APPLICABILITY

The present disclosure can provide an electromagnetic wave absorber which makes it possible to set the frequency band of an electromagnetic wave incident thereon which is an object to be absorbed with more flexibility than conventional electromagnetic wave absorbers, irrespective of the direction of polarization of the electromagnetic wave, and is suitable for use as electromagnetic wave absorbers.

### REFERENCE SIGNS LIST

1, 1b, and 1c: Electromagnetic wave absorber, 10: Resonator unit, 20: SiW resonator, 21: Front surface conductor layer (Front surface conductor pattern), 22: Penetration conductor (penetration through hole array), 23: Coupling slot, 24: Internal layer conductor pattern, 25: Dielectric layer, 26: Rear surface conductor layer (solid conductor pattern), 27: Multilayered dielectric substrate, 28: Inner layer coupling hole, L1 to L4: Length in lateral direction of SIW resonator, and Ls: Length in longitudinal direction of coupling slot.

1. An electromagnetic wave absorber comprising multiple resonators, each of which has SIW resonators, each of which has: a front surface conductor layer formed with a coupling slot into which an electromagnetic wave is introduced; a rear surface conductor layer which is placed opposite to the front surface conductor layer; and a penetration conductor to electrically connect the front surface conductor layer and the rear surface conductor layer, the SIW resonators being different in resonance frequency from each other, and disposed in a multistage form in a lateral direction of the coupling slot,
wherein the multiple resonators are disposed in a planar form in such a way that the longitudinal direction of the coupling slots belonging to each of the multiple resonators is oriented in two or more directions,
a length in longitudinal direction of the coupling slots is longer than a half wavelength at a resonance frequency of the SIW resonator having said coupling slots.

2. The electromagnetic wave absorber according to claim 1, wherein
the coupling slots belonging to each of the multiple resonators are equal in orientation in longitudinal direction thereof to each other, and
the multiple resonators are disposed in such a way that an orientation in the longitudinal direction of the coupling slots belonging to each of the multiple resonators is different from an orientation in the longitudinal direction of the coupling slots belonging to at least one of the multiple resonators adjacent to said each of the multiple resonators.

3. The electromagnetic wave absorber according to claim 1, wherein
each of the multiple resonators has a square planar shape, and the multiple resonators are disposed in a planar form in such a way that the longitudinal direction of the coupling slots belonging to each of the multiple resonators is oriented in two directions.

4. The electromagnetic wave absorber according to claim 1, wherein
each of the multiple resonators has a non-square rectangular planar shape, and the multiple resonators are disposed in a planar form in such a way that the longitudinal direction of the coupling slots belonging to each of the multiple resonators is oriented in two directions.

5. The electromagnetic wave absorber according to claim 1, wherein
each of the multiple resonators has a diamond planar shape whose one of interior angles is 60 degrees, and the multiple resonators are disposed in a planar form in such a way that the longitudinal direction of the coupling slots belonging to each of the multiple resonators is oriented in three directions.

6. The electromagnetic wave absorber according to claim 1, wherein
the multiple resonators are classified into at least two types according to the longitudinal direction of the coupling slots belonging to each of the multiple resonators, and the classified multiple resonators of at least the two types are disposed in a mosaic periodic pattern.

7. The electromagnetic wave absorber according to claim 1, wherein
the front surface conductor layer has N+1 (N>=2) conductor layers and N dielectric layers each of which is sandwiched between two different ones of the N+1 conductor layers, and is located in a main surface of a multilayered dielectric substrate in which two adjacent ones included in the N dielectric layers are partially connected, the rear surface conductor layer is located in a surface opposite to the main surface of the multilayered dielectric substrate, the penetration conductors electrically connect the front surface conductor layer and the rear surface conductor layer, to form an electrically closed region together with the front surface conductor layer and the rear surface conductor layer, the main surface of the multilayered dielectric substrate, which is surrounded by the penetration conductors, has a region in which the front surface conductor layer is formed, and a dielectric exposed region in which a dielectric layer is exposed by the coupling slot formed in the front surface conductor layer, and a region in which the two adjacent dielectric layers are partially connected is inside the electrically closed region.

8. The electromagnetic wave absorber according to claim 1, wherein
in each of the multiple resonators, the SIW resonators different in resonance frequency from each other are disposed so as to form a multistage configuration, and each of the multiple resonators has a predetermined resonance frequency band, and
the multiple resonators are equal in resonance frequency band to each other.

9. The electromagnetic wave absorber according to claim 1, wherein
in each of the multiple resonators, the SIW resonators different in resonance frequency from each other are disposed so as to form a multistage configuration, and each of the multiple resonators has a predetermined resonance frequency band, and
the resonance frequency band of one of the multiple resonators overlaps at least partially with the resonance frequency band of another one of the multiple resonators.

10. An electromagnetic wave absorber comprising multiple resonators, each of which has SIW resonators, each of which has: a front surface conductor layer formed with a coupling slot into which an electromagnetic wave is introduced; a rear surface conductor layer which is placed opposite to the front surface conductor layer; and a penetration conductor to electrically connect the front surface conductor layer and the rear surface conductor layer, the SIW resonators being equal in resonance frequency to each other, and disposed in a multistage form in a lateral direction of the coupling slot,
wherein the multiple resonators are different in resonance frequency from each other,
the multiple resonators are disposed in a planar form in such a way that the longitudinal direction of the coupling slots belonging to each of the multiple resonators is oriented in two or more directions.
